(19) United States
(12) Patent Application Publication
(10) Pub. No.: US 2018/0294319 A1
(43) Pub. Date: Oct. 11, 2018

(54) WOLED DISPLAY DEVICE

(71) Applicant: Shenzhen China Optoelectronics Technology Co., Ltd., Shenzhen City (CH)

(72) Inventor: Yang LIU, Shenzhen City (CN)

(21) Appl. No.: 15/540,027

(22) PCT Filed: May 18, 2017
(86) PCT No.: PCT/CN2017/084789

§ 371 Date: Jun. 27, 2017

(30) Foreign Application Priority Data
Apr. 10, 2017 (CN) 201710229745.9

(51) Int. Cl. H01L 27/32; H01L 51/52; H01L 51/50

(52) U.S. Cl. CPC H01L 27/3213; H01L 51/5206; H01L 27/3246; H01L 51/5056; H01L 51/5072; H01L 51/5221

(57) ABSTRACT

The invention provides a WOLED display device, comprising: a substrate, and a WOLED device disposed on the substrate; the substrate comprising a plurality of pixel areas, arranged in an array; the WOLED device comprising: an anode layer, a hole injection layer (HIL) disposed on the anode layer, and a plurality of light-emitting layers (EML), wherein a charge generation layer (CGL) being disposed between two adjacent EML layers, and the HIL layer contacting the anode layer; the HIL layer and/or at least a CGL layer being disposed correspondingly to the plurality of pixel areas, and broken off above banks between the two adjacent pixel areas; the present invention improves the physical structure of the WOLED display device so that the HIL layer and CGL layer have no lateral conduction characteristics for reduced pixel distance and higher driving voltage, leading to effective avoidance of light leakage.

### BACKGROUND OF THE INVENTION

### 1. Field of the Invention

The present invention relates to the field of display, and in particular to a white organic light-emitting diode (WOLED) display device.

### 2. The Related Arts

The active matrix flat panel display, with advantages of thin body, saving power, no radiation and many others, has been widely used. In particular, the organic light-emitting diode (OLED) display technology is a highly promising flat panel display technology, which has a very excellent display performance; especially, with characteristics of self-luminance, simple structure, ultra-thinness, fast response speed, wide viewing angle, low power consumption and ability to realize flexible display, the OLED is known as the “dream display”. Coupled with much smaller production equipment investment than the thin film transistor liquid crystal display (TFT-LCD), the OLED attracts attention from major display manufacturers and has become the chosen display technology for the third generation of display device. At present, OLED is on the brink of mass production and, with further study of new technology continuing to emerge, OLED display devices will make a breakthrough development.

To achieve full color for the OLED display, an approach is to use the side-by-side structure with the red, green, and blue (RGB) sub-pixels to emit light respectively, and another approach is to use the tandem WOLED+CF structure with white organic light emitting diode (WOLED) and color filter (CF) layer in stack. In WOLED, two or more light-emitting layers are connected by a charge generation layer (CGL) to emit white light, which passes through the CF layer to obtain RGB monochromatic light. As the light-emitting layers are stacked, the structure is called tandem structure.

In recent years, the display technology continues to develop towards high-resolution: from the 2K panel to the current mainstream 4K panel, and the continuing towards 8K panel. To ensure a certain aperture ratio and luminance, the space of the bank areas between the sub-pixels in the display panel must become smaller, and the driving voltage of a single pixel is gradually increased. The decrease in pixel spacing and the increase in driving voltage cause the phenomenon wherein un-driven sub-pixel next to the driven sub-pixels in the WOLED display panel will appear slightly illuminating, called light leakage phenomenon. The light leakage reduces the display of the color gamut, and leads to the decline in display quality.

In WOLED device, two layers of materials may lead to light leakage. One is the hole injection layer (HIL) material, and the other is the charge generation layer (CGL) material. As shown in FIGS. 1-2, the known WOLED elements comprises, from the bottom up, anode layer 10, an HIL layer 11, a first hole transport layer (HTL) 12, a first light-emitting layer (EML) 13, a first electron transport layer (ETL) 14, a CGL layer 12, a second HTL layer 16, a second EML layer 17, a second ETL 18 and a cathode layer 19; wherein, the anode layer 18 has a pattern corresponding to the layout of the sub-pixels in the display panel, and the other layers are of the entire-surface structure and because the material of the HIL layer 11 and the material of the CGL layer 15 have a function of certain lateral charge transfer, which provides the possibility for lateral conduction of the charge, leading to light leakage under certain conditions. As shown in FIG. 1, for the relatively large spacing between pixels and low drive voltage, the charge is basically along a longitudinal conduction, and no light leakage occurs. As shown in FIG. 2, for the relatively large spacing between pixels and higher driving voltage, a small amount of charges may be laterally conducted to the adjacent sub-pixels in the HIL layer 11 and the CGL layer 15, so that adjacent sub-pixels are also driven and weakly illuminating.

### SUMMARY OF THE INVENTION

The object of the present invention is to provide a WOLED display device, able to effectively avoid light leakage under the condition of small pixel space and high driving voltage.

To achieve the above object, the present invention provides a white organic light-emitting diode (WOLED) display device, comprising: a substrate, and a WOLED device disposed on the substrate;

the substrate comprising a plurality of pixel areas, arranged in an array;

the WOLED device comprising: an anode layer, a hole injection layer (HIL) disposed on the anode layer, and a plurality of light-emitting layers (EML), wherein a charge generation layer (CGL) being disposed between two adjacent EML layers, and the HIL layer contacting the anode layer;

the HIL layer and/or at least a CGL layer being disposed correspondingly to the plurality of pixel areas, and broken off above the bank areas between the two adjacent pixel areas.

According to a preferred embodiment of the present invention, the plurality of WOLED elements further comprises a plurality of hole transport layers (HTL), a plurality of electron transport layers (ETL), and a cathode layer.

According to a preferred embodiment of the present invention, the HIL layer and the CGL layer both cover the plurality of pixel areas.

According to a preferred embodiment of the present invention, the EML layer, HTL layer, ETL layer, and cathode layer are all of an entire-surface structure covering the plurality of pixel areas.

According to a preferred embodiment of the present invention, the HIL layer and/or at least a CGL layer is formed by vapor deposition on the corresponding plurality of pixel areas with fine metal mask, the fine metal mask comprises a plurality of pixel openings corresponding to the plurality of pixel areas in one-on-one manner and having the same shape as the pixel areas.

According to a preferred embodiment of the present invention, the WOLED device comprises two EML layers, and the two EML layers are a first EML layer and a second EML layer;

the f WOLED device comprises two HTL layers, and the two HTL layers are a first HTL layer and a second HTL layer;

the WOLED device comprises two ETL layers, and the two ETL layers are a first ETL layer and a second ETL layer;

in the WOLED device, the HIL layer is disposed on the anode layer, the first HTL layer is disposed on the HIL layer, the first EML layer is disposed on the first HTL layer, the first ETL layer is disposed on the first EML layer, the CGL layer is disposed on the first ETL layer, the second HTL layer is disposed on the CGL layer, the second EML layer is disposed on the second HTL layer, the second ETL layer is disposed on the second EML layer, and the cathode layer is disposed on the second ETL layer.

According to a preferred embodiment of the present invention, the HIL layer and the CGL layer are both disposed correspondingly to the plurality of pixel areas, and broken off above the bank areas between the two adjacent pixel areas.

According to a preferred embodiment of the present invention, the HIL layer is disposed correspondingly to the plurality of pixel areas, and broken off above the bank areas between the two adjacent pixel areas;

and the CGL layer is of an entire-surface structure.

According to a preferred embodiment of the present invention, the CGL layer is disposed correspondingly to the plurality of pixel areas, and broken off above the bank areas between the two adjacent pixel areas;

and the HIL layer is of an entire-surface structure.

The present invention also provides a white organic light-emitting diode (WOLED) display device, comprising: a substrate, and a WOLED device disposed on the substrate;

the substrate comprising a plurality of pixel areas, arranged in an array;

the WOLED device comprising: an anode layer, a hole injection layer (HIL) disposed on the anode layer, and a plurality of light-emitting layers (EML), wherein a charge generation layer (CGL) being disposed between two adjacent EML layers, and the HIL layer contacting the anode layer;

the HIL layer and/or at least a CGL layer being disposed correspondingly to the plurality of pixel areas, and broken off above the bank areas between the two adjacent pixel areas;

wherein the plurality of WOLED elements further comprising a plurality of hole transport layers (HTL), a plurality of electron transport layers (ETL), and a cathode layer;

wherein the HIL layer and the CGL layer both covering the plurality of pixel areas.

Compared to the known techniques, the present invention provides the following advantages: the present invention provides a WOLED display device, comprising: a substrate, and a WOLED device disposed on the substrate; the substrate comprising a plurality of pixel areas, arranged in an array; the WOLED device comprising: an anode layer, a hole injection layer (HIL) disposed on the anode layer, and a plurality of light-emitting layers (EML), wherein a charge generation layer (CGL) being disposed between two adjacent EML layers, and the HIL layer contacting the anode layer; the HIL layer and/or at least a CGL layer being disposed correspondingly to the plurality of pixel areas, and broken off above the bank areas between the two adjacent pixel areas; the present invention improves the physical structure of the WOLED display device so that the HIL layer and CGL layer does not show lateral conduction characteristics under the conditions of reduced pixel gaps and higher driving voltage, leading to effective avoidance of light leakage.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing a known WOLED display device not leaking light under the conditions of larger pixel banks and lower driving voltage;

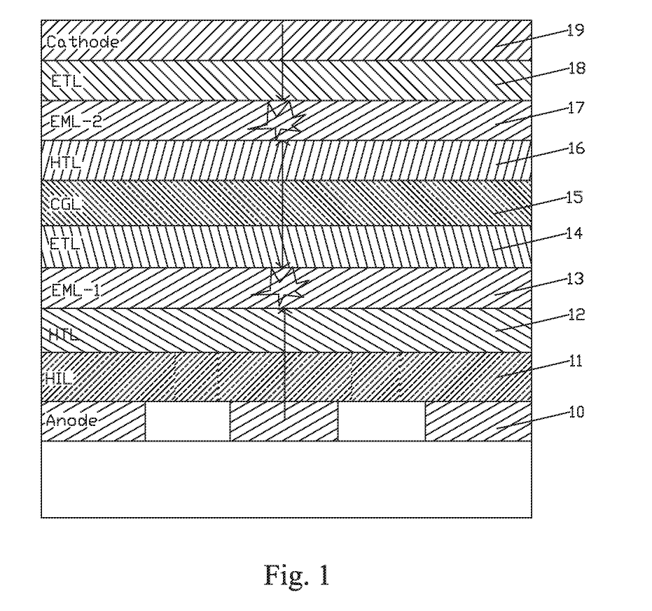

FIG. 2 is a schematic view showing a known WOLED display device leaking light under the conditions of smaller pixel banks and higher driving voltage;

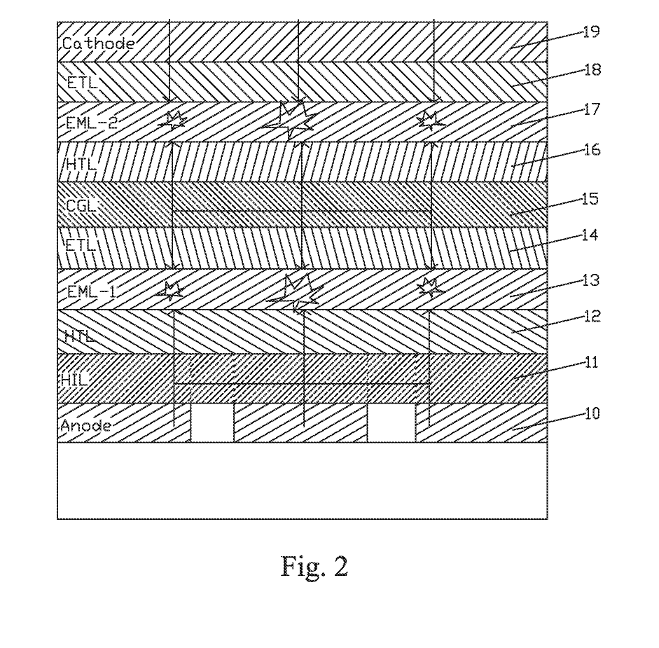

FIG. 3 is a schematic view showing the structure of WOLED element in the first embodiment of the WOLED display device according to the present invention;

FIG. 4 is a schematic view showing the structure of WOLED element in the second embodiment of the WOLED display device according to the present invention;

FIG. 5 is a schematic view showing the structure of WOLED element in the third embodiment of the WOLED display device according to the present invention.

### DETAILED DESCRIPTION OF THE PREFERRED EMBODIMENTS

To further explain the technical means and effect of the present invention, the following refers to embodiments and drawings for detailed description.

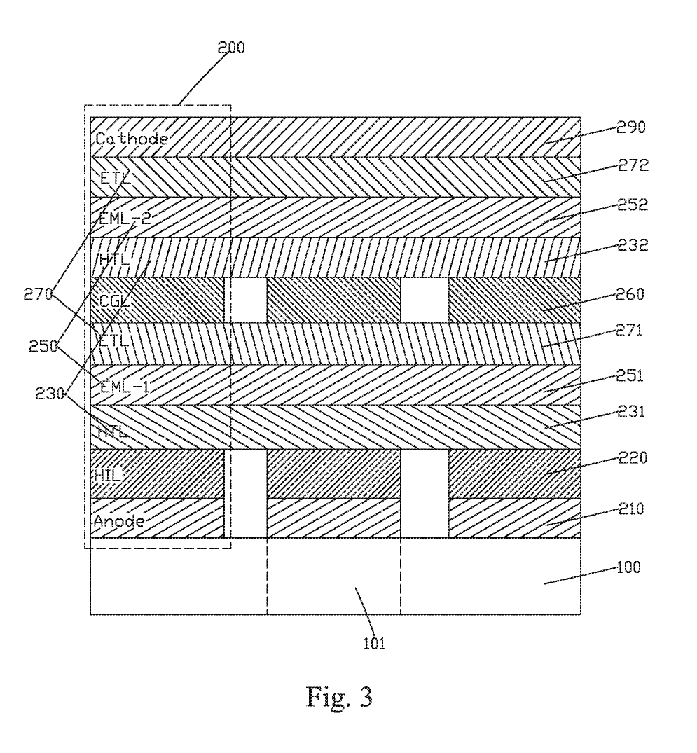

Refer to FIG. 3. FIG. 3 is a schematic view showing the structure of WOLED element in the first embodiment of the WOLED display device according to the present invention. As shown in FIG. 3, the first embodiment of the WOLED display device of the present invention comprises: a substrate 100, and a plurality of WOLED elements 200 disposed on the substrate 100;

the substrate 100 comprising a plurality of pixel areas 101, arranged in an array;

the plurality of WOLED elements 200 comprising: an anode layer 210, a hole injection layer (HIL) 220 disposed on the anode layer 210, and a plurality of light-emitting layers (EML) 250 disposed above the HIL layer 220, wherein a charge generation layer (CGL) 260 being disposed between two adjacent EML layers 250, that is, if the plurality of WOLED elements 200 comprising N+1 EML layers 250, N CGL layers 260 being disposed;

the HIL layer 220 contacting the anode layer 210;

the HIL layer 220 and/or at least a CGL layer 260 being disposed correspondingly to the plurality of pixel areas 101, and broken off above the bank areas between the two adjacent pixel areas 101.

Specifically, the plurality of WOLED elements 200 further comprises a plurality of hole transport layers (HTL) 230 and a plurality of electron transport layers (ETL) 240 corresponding to the EML layers 250, and a cathode layer 260 disposed at the topmost layer.

Specifically, the HIL layer 220 and the CGL layer 260 both cover the plurality of pixel areas 101.

Specifically, the EML layer 250, HTL layer 230, ETL layer 270, and cathode layer 290 are all of an entire-surface structure covering the plurality of pixel areas 101, and therefore, can be formed by entire-surface vapor deposition with an open mask.

Specifically, the HIL layer 220 and/or at least a CGL layer 260 is formed by vapor deposition on the corresponding plurality of pixel areas 101 with an fine metal mask to achieve breaking-off above the bank areas between two adjacent pixel areas 101, and the fine metal mask comprises a plurality of pixel openings corresponding to the plurality of pixel areas 101 in one-on-one manner and having the same shape as the pixel areas 101.

Specifically, the plurality of WOLED elements 200 comprises two EML layers 250, two HTL layers 230, and two ETL layers 270; and the two EML layers 250 are a first EML layer 251 and a second EML layer 252; that is, the plurality of WOLED elements 200 comprises a CGL layer 260, the two HTL layers 230 are a first HTL layer 231 and a second HTL layer 232; the two ETL layers 270 are a first ETL layer 271 and a second ETL layer 272.

Specifically, in the plurality of WOLED elements 200, the HIL layer 220 is disposed on the anode layer 210, the first HTL layer 231 is disposed on the HIL layer 220, the first EML layer 251 is disposed on the first HTL layer 231, the first ETL layer 271 is disposed on the first EML layer 251, the CGL layer 260 is disposed on the first ETL layer 271, the second HTL layer 232 is disposed on the CGL layer 260, the second EML layer 252 is disposed on the second HTL layer 232, the second ETL layer 272 is disposed on the second EML layer 252, and the cathode layer 290 is disposed on the second ETL layer 272.

Specifically, the HIL layer 220 and the CGL layer 260 are both disposed correspondingly to the plurality of pixel areas 101, and broken off above bank areas between the two adjacent pixel areas 101. However, when a plurality of CGL layers 260 is employed in the present invention, the plurality of CGL layers 260 can all be broken off above the bank areas between two adjacent pixel areas 101, or with only one or more layers broken off above the bank areas between two adjacent pixel areas 101.

In the aforementioned WOLED display device, the present invention improves the physical structure of the WOLED display device by breaking off the HIL layer and/or at least a CGL layer above the bank areas between two adjacent pixel areas, so that the HIL layer and CGL layer does not show lateral conduction characteristics under the conditions of reduced pixel distance and higher driving voltage, leading to effective avoidance of light leakage, solving the problem of reduced color gamut caused by leakage and improving display quality of the products.

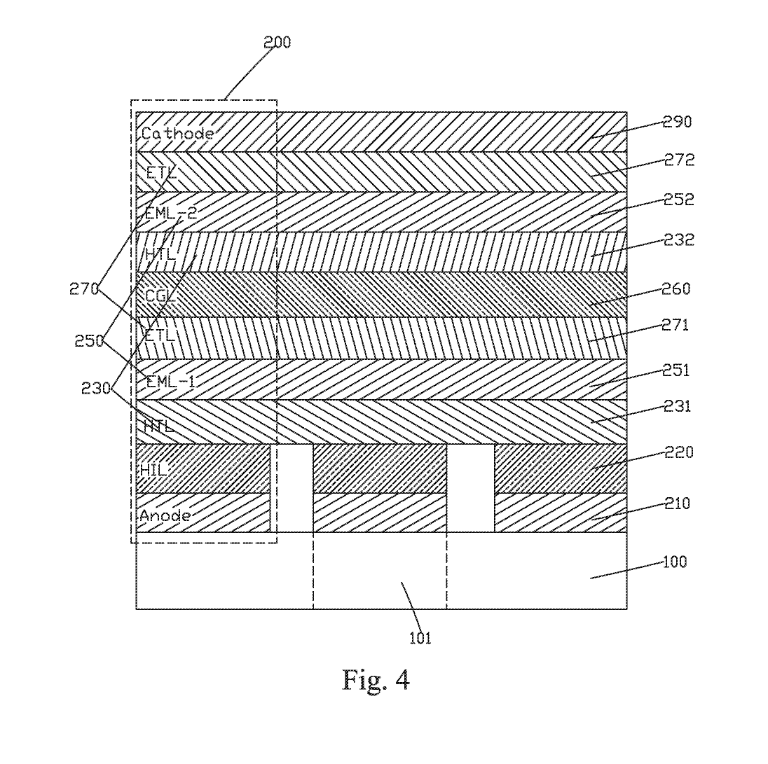

Refer to FIG. 4. FIG. 4 is a schematic view showing the structure of WOLED element in the second embodiment of the WOLED display device according to the present invention. Compared to the first embodiment, in the present embodiment, the HIL layer 220 is disposed correspondingly to the plurality of pixel areas 101, and broken off above banks between the two adjacent pixel areas 101; and the CGL layer 260 is of an entire-surface structure. The remaining is the same as the first embodiment, and the details will not be repeated here.

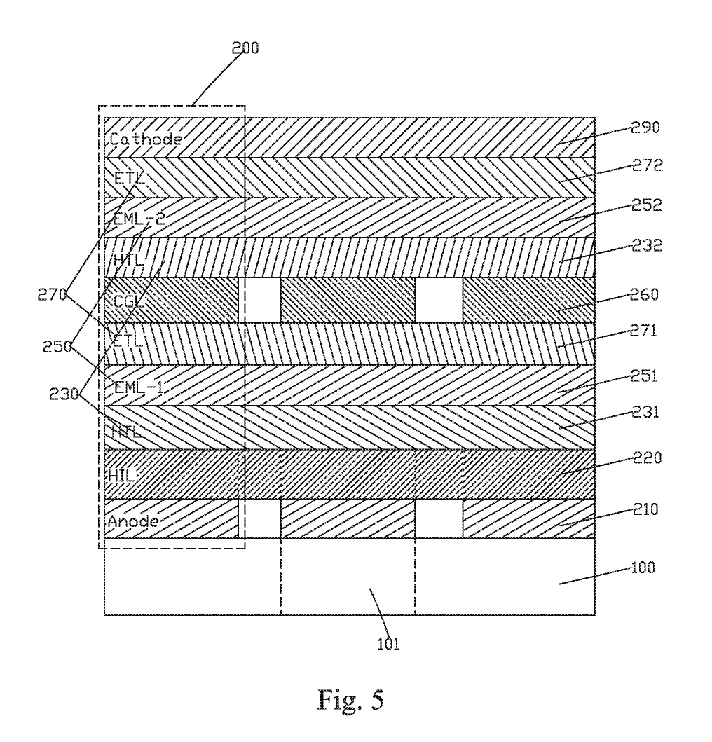

Refer to FIG. 5. FIG. 5 is a schematic view showing the structure of WOLED element in the third embodiment of the WOLED display device according to the present invention. Compared to the first embodiment, in the present embodiment, the CGL layer 260 is disposed correspondingly to the plurality of pixel areas 101, and broken off above banks between the two adjacent pixel areas 101; and the HIL layer 220 is of an entire-surface structure. The remaining is the same as the first embodiment, and the details will not be repeated here.

In summary, the present invention provides a WOLED display device, comprising: a substrate, and a plurality of WOLED elements disposed on the substrate; the substrate comprising a plurality of pixel areas, arranged in an array; the plurality of WOLED elements comprising: an anode layer, a hole injection layer (HIL) disposed on the anode layer, and a plurality of light-emitting layers (EML), wherein a charge generation layer (CGL) being disposed between two adjacent EML layers, and the HIL layer contacting the anode layer; the HIL layer and/or at least a CGL layer being disposed correspondingly to the plurality of pixel areas, and broken off above banks between the two adjacent pixel areas; the present invention improves the physical structure of the WOLED display device so that the HIL layer and CGL layer does not show lateral conduction characteristics under the conditions of reduced pixel distance and higher driving voltage, leading to effective avoidance of light leakage.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A white organic light-emitting diode (WOLED) display device, comprising:
a substrate, and a WOLED device disposed on the substrate;
the substrate comprising a plurality of pixel areas, arranged in an array;
the WOLED device comprising: an anode layer, a hole injection layer (HIL) disposed on the anode layer, and a plurality of light-emitting layers (EML), wherein a charge generation layer (CGL) being disposed between two adjacent EML layers, and the HIL layer contacting the anode layer;
the HIL layer and/or at least a CGL layer being disposed correspondingly to the plurality of pixel areas, and broken off above banks between the two adjacent pixel areas.

2. The WOLED display device as claimed in claim 1, wherein the WOLED device further comprises a plurality of hole transport layers (HTL), a plurality of electron transport layers (ETL), and a cathode layer.

3. The WOLED display device as claimed in claim 1, wherein he HIL layer and the CGL layer both cover the plurality of pixel areas.

4. The WOLED display device as claimed in claim 2, wherein the EML layer, HTL layer, ETL layer, and cathode layer are all of an entire-surface structure covering the plurality of pixel areas.

5. The WOLED display device as claimed in claim 1, wherein the HIL layer and/or at least a CGL layer is formed by vapor deposition on the corresponding plurality of pixel areas with an fine metal mask, the fine metal mask comprises a plurality of pixel openings corresponding to the plurality of pixel areas in one-on-one manner and having the same shape as the pixel areas.

6. The WOLED display device as claimed in claim 2, wherein the WOLED device comprises two EML layers, and the two EML layers are a first EML layer and a second EML layer;
the WOLED device comprises two HTL layers, and the two HTL layers are a first HTL layer and a second HTL layer;
the WOLED device comprises two ETL layers, and the two ETL layers are a first ETL layer and a second ETL layer;
in the WOLED device, the HIL layer is disposed on the anode layer, the first HTL layer is disposed on the HIL layer, the first EML layer is disposed on the first HTL layer, the first ETL layer is disposed on the first EML layer, the CGL layer is disposed on the first ETL layer, the second HTL layer is disposed on the CGL layer, the second EML layer is disposed on the second HTL layer, the second ETL layer is disposed on the second EML layer, and the cathode layer is disposed on the second ETL layer.

7. The WOLED display device as claimed in claim 6, wherein the HIL layer and the CGL layer are both disposed correspondingly to the plurality of pixel areas, and broken off above banks between the two adjacent pixel areas.

8. The WOLED display device as claimed in claim 6, wherein the HIL layer is disposed correspondingly to the plurality of pixel areas, and broken off above banks between the two adjacent pixel areas; and
the CGL layer is of an entire-surface structure.

9. The WOLED display device as claimed in claim 6, wherein the CGL layer is disposed correspondingly to the plurality of pixel areas, and broken off above banks between the two adjacent pixel areas; and
the HIL layer is of an entire-surface structure.

10. A white organic light-emitting diode (WOLED) display device, comprising:
a substrate, and a WOLED device disposed on the substrate;
the substrate comprising a plurality of pixel areas, arranged in an array;
the WOLED device comprising: an anode layer, a hole injection layer (HIL) disposed on the anode layer, and a plurality of light-emitting layers (EML), wherein a charge generation layer (CGL) being disposed between two adjacent EML layers, and the HIL layer contacting the anode layer;
the HIL layer and/or at least a CGL layer being disposed correspondingly to the plurality of pixel areas, and broken off above banks between the two adjacent pixel areas;
wherein the WOLED device further comprising a plurality of hole transport layers (HTL), a plurality of electron transport layers (ETL), and a cathode layer;
wherein he HIL layer and the CGL layer both covering the plurality of pixel areas.

11. The WOLED display device as claimed in claim 10, wherein the EML layer, HTL layer, ETL layer, and cathode layer are all of an entire-surface structure covering the plurality of pixel areas.

12. The WOLED display device as claimed in claim 10, wherein the HIL layer and/or at least a CGL layer is formed by vapor deposition on the corresponding plurality of pixel areas with an fine metal mask, the fine metal mask comprises a plurality of pixel openings corresponding to the plurality of pixel areas in one-on-one manner and having the same shape as the pixel areas.

13. The WOLED display device as claimed in claim 10, wherein the WOLED device comprises two EML layers, and the two EML layers are a first EML layer and a second EML layer;
the WOLED device comprises two HTL layers, and the two HTL layers are a first HTL layer and a second HTL layer;
the WOLED device comprises two ETL layers, and the two ETL layers are a first ETL layer and a second ETL layer;
in the WOLED device, the HIL layer is disposed on the anode layer, the first HTL layer is disposed on the HIL layer, the first EML layer is disposed on the first HTL layer, the first ETL layer is disposed on the first EML layer, the CGL layer is disposed on the first ETL layer, the second HTL layer is disposed on the CGL layer, the second EML layer is disposed on the second HTL layer, the second ETL layer is disposed on the second EML layer, and the cathode layer is disposed on the second ETL layer.

14. The WOLED display device as claimed in claim 13, wherein the HIL layer and the CGL layer are both disposed correspondingly to the plurality of pixel areas, and broken off above banks between the two adjacent pixel areas.

15. The WOLED display device as claimed in claim 13, wherein the HIL layer is disposed correspondingly to the plurality of pixel areas, and broken off above banks between the two adjacent pixel areas; and
the CGL layer is of an entire-surface structure.

16. The WOLED display device as claimed in claim 13 wherein the CGL layer is disposed correspondingly to the plurality of pixel areas, and broken off above banks between the two adjacent pixel areas; and
the HIL layer is of an entire-surface structure.
